(19) United States
(12) Patent Application Publication
(10) Pub. No.: US 2009/0243897 A1
(43) Pub. Date: Oct. 1, 2009

(54) METHOD AND APPARATUS FOR ENTERING ALPHANUMERIC DATA VIA KEYPADS OR DISPLAY SCREENS

(76) Inventors: Wayne A. Davidson, Leesburg, VA (US); Beth L. Davidson, Leesburg, VA (US)

Correspondence Address: MCANDREWS HELD & MALLOY, LTD, 500 WEST MADISON STREET, SUITE 3400, CHICAGO, IL, 60661, US

(21) Appl. No.: 12/174,798

(22) Filed: Jul. 17, 2008

Related U.S. Application Data
(60) Provisional application No. 61/041,350, filed on Apr. 1, 2008.

(51) Int. Cl. H03M 11/00

(52) U.S. Cl. 341/22

(57) ABSTRACT

A method and apparatus for entry of alphabetical characters and numeric characters using a touch pad or display screen on an electronic device (e.g., cell phone, GPS navigation system). The touch pad or display has numbers and letters displayed in an optimal arrangement to allow rapid entry of characters by depressing, touching or sliding of a finger. Electronic circuitry beneath the pad or display can detect whether the user is fully depressing, slightly touching, or sliding a finger across the pad or display. Recognition of the specific finger action indicates the specific letters, numbers, or special symbols to be entered into the device application (e.g., SMS text, email, navigation, etc.)

### CROSS-REFERENCE TO RELATED APPLICATIONS/INCORPORATION BY REFERENCE

This application claims priority to U.S. Application Serial No. 61/041,350 filed Apr. 1, 2008, which is incorporated by reference herein in its entirety.

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

The present invention relates generally to electronic devices such as cell phones, GPS navigation systems, personal digital assistants (PDA), media players, and portable computers. More particularly, the present invention relates to the keypads and display screens that are used to enter text and numbers into said devices.

### BACKGROUND OF THE INVENTION

Current apparatus and methods for entering text or numeric information into portable electronic devices are difficult to use and learn. These devices, for example, cell phones, email devices, hand-held calculators, navigation systems, and the like, comprise keypads which are very small and cumbersome in use, allowing for inaccurate entry of data.

Heretofore, alphabetic and numeric characters are entered by pressing one of a plurality of keys, each key being associated with a particular alphanumeric character to be entered. The key may be pressed once, or else multiple times, to indicate a specific character. The key arrangement may be a “Qwerty” type or in alphabetic order. Where there are small keying areas, a stylus may be used to activate or press the key area.

Alternatively, a stylus may be used to write or draw an individual character, typically on a glass surface of a display, to enter the character corresponding to the drawn character. However, such displays which are formed of glass are slippery, and provide no tactile feedback to the user. In addition, direct viewing of the surface by the user is important.

It is therefore, an object of the present invention to provide a keying apparatus and method which is easy to learn, can be performed quickly, and does not require the user to view the keypad.

### BRIEF SUMMARY OF THE INVENTION

These and other objects of the invention are achieved in a system and method for key entry of individual alphabetic or numeric characters. A specified finger movement identifies an individual character in an easy to perform and easy to remember fashion. In one embodiment, twelve separate physical or electronically displayed keys are pressed, touched or moved across in a specified manner to identify one of twenty-six alphabetical characters, the numbers zero through nine, punctuation marks and various commands.

The selection of a specific letter, number or command is performed by one of three types of finger movements: 1) pressing, (2) lightly touching, or 3) sliding of the finger.

Capacitance Resistance electronics may be located behind the keypad to detect touching and sliding movements of the finger (angle, distance, and speed, for example). Such capacitance resistance circuitry may dynamically determine the x and y coordinates of the finger as it touches or slides across the touchpad or display. A microprocessor controlled by software maps the dynamic x and y coordinates to a specific number, letter, punctuation, symbol (e.g., #) or control function (e.g., enter). Such capacitance resistance circuitry can distinguish between touching and sliding by determining whether the finger has moved after it is first touched and before it is removed from the keypad surface.

The keypad may detect pressing on the keypad in one of two ways: 1) emulated buttons (e.g., raised surface) with supporting capacitance resistance electronics or 2) contact switches in designated places on the pad.

The pad may be specifically designed to provide optimal resistance and tactile feedback.

The letters are specifically arranged according to the frequency of word and letter usage, thus facilitating rapid entry of text.

Some of the specific advantages of this innovative design are:

1. The invention requires less buttons (physical or emulated) compared to the current art which requires 35 or more (e.g., a Blackberry device)—thus reducing the size and cost of the keypad.

2. The invention allows both rapid number dialing and rapid texting compared to the current art which is optimized for only one function (i.e., either dialing or texting. For example, with a Blackberry device it is difficult to dial numbers since the keys are small relative to the finger.

3. The invention facilitates rapid learning since the letters and words are spatially oriented which aids in the cognitive memorization process.

4. The invention facilitates fast selection of the most common letters since they are more easily and quickly selected than less common letters.

5. The invention facilitates the rapid creation of words since letters are adjacent to the most common preceding and/or following letters in common letter sequences.

6. The invention allows dialing numbers and entering text without looking at the keypad, since there are significantly less physical or emulated buttons (e.g., 12 vs. 35).

7. The invention is extremely flexible to use since one thumb, two thumbs, one finger, or multiple fingers can be used to enter numbers and text based on the user's preference and/or the specific keypad design.

8. Even though the main embodiment described here is a small physical keypad for use on devices such as a cell phone, the invention is equally applicable to a large variety of embodiments such as touch-sensitive display screens on devices such as an Apple iPhone or a laptop computer.

9. The invention will allow young children, elderly, and physically handicapped (e.g., visually impaired, paraplegics) to learn and use text input devices.

These and other advantages, aspects and novel features of the present invention, as well as details of an illustrated embodiment thereof, will be more fully understood from the following description and drawings.

### BRIEF DESCRIPTION OF THE DRAWINGS

FIG. 1 is a top view of the touch pad or display in accordance with an embodiment of the present invention.

FIG. 2 is a diagram showing how the letters S, A, N, T, E, I, H, O, R, the “space” key, the “backspace key,” and the “number lock” key are activated by pressing or touching of the physical or emulated key which activates the associated contact switch or capacitance electronics.

FIG. 3 is a diagram showing how the numbers 0 to 9, *, and # are activated by pressing or touching of the physical or emulated key which activates the associated contact switch or capacitance electronics.

FIG. 4 is a diagram showing how the letters V, W, B, C, D, X, P, Q, L, M, J, K, F, G, Y, U, Z, “caps lock,” “symbol shift,” and “return” are activated by sliding of the finger in the designated location and direction.

FIG. 5 is a diagram showing the complete layout of the keypad with all numbers, letters, punctuation, and control shown. FIG. 5 also shows how letters are positioned on the keypad according to common sequencing of common words or partial words to speed the entry of text into the keypad.

FIG. 6 shows suggested layouts for different types of cell phones.

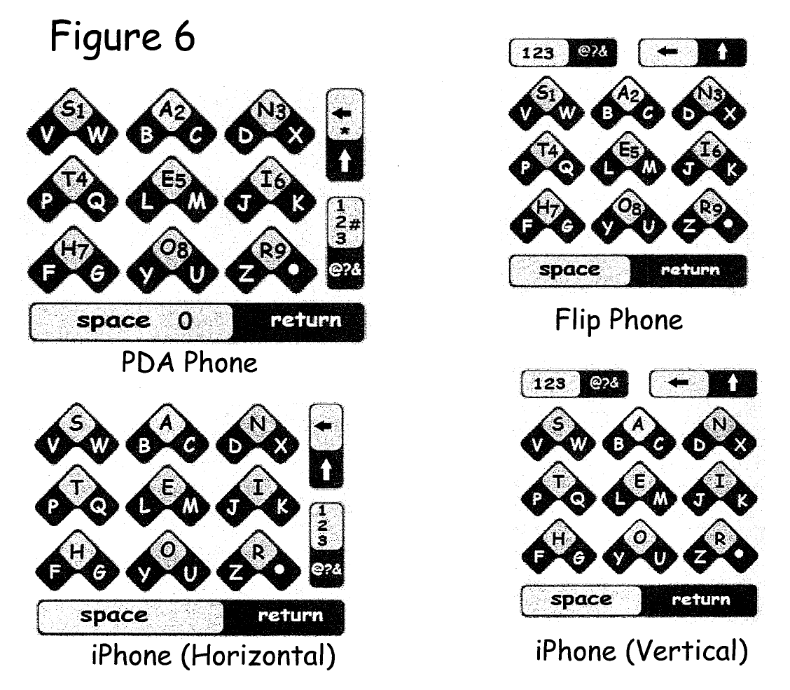

FIG. 7 shows other example embodiments of the invention.

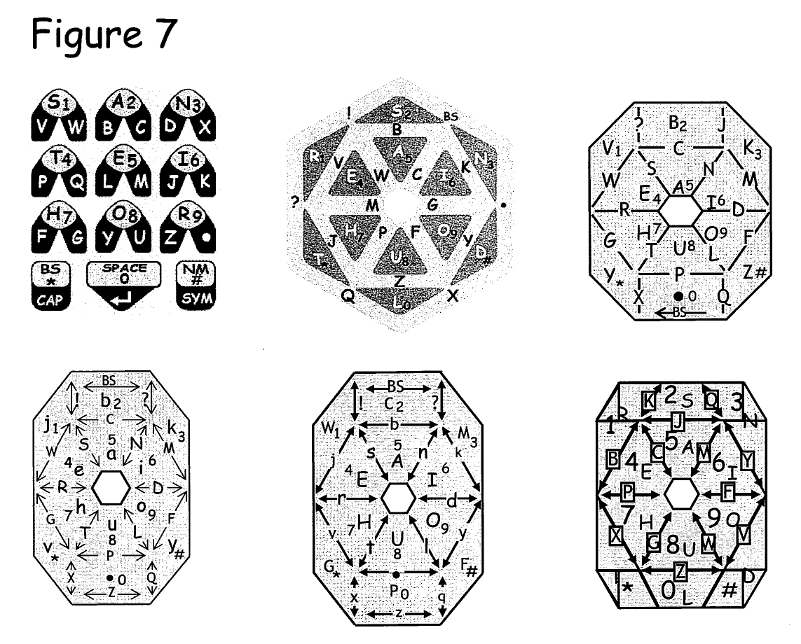

Table 1 provides statistical information on the frequency of letter usage which may be used to optimize the layout of alphabetic characters and numbers on the touch pad or display to facilitate rapid text entry.

Table 2 shows the frequency of letter sequencing and the frequency of word use that may be used to optimize the layout of the keypad or display screen layout.

### DETAILED DESCRIPTION OF THE PREFERRED EMBODIMENT

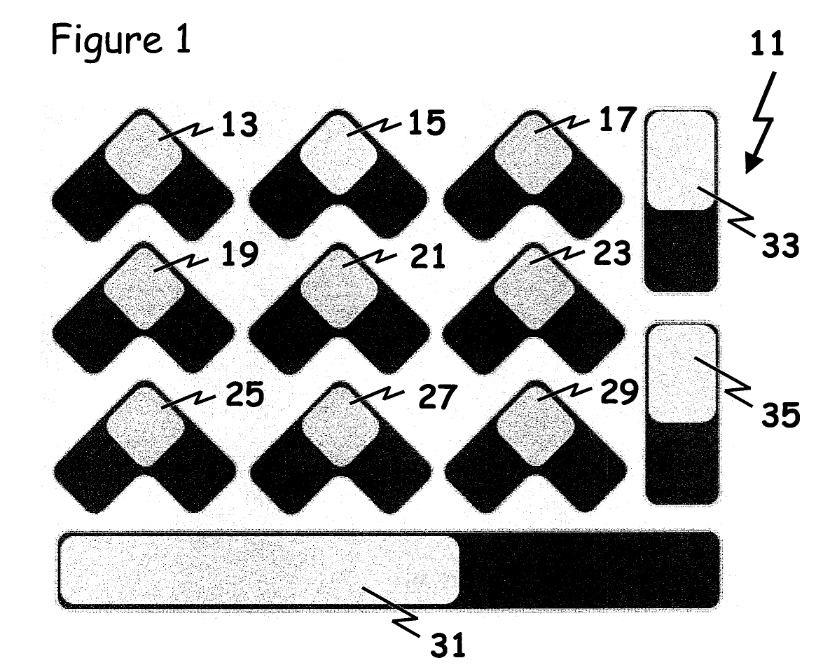

Referring to FIG. 1, a keypad 11 includes nine separate keys 13, 15, 17, 19, 21, 23, 25, 27, 29. The keys are diamond in shape and occupy most of the area of keypad 11 except the far right and bottom of the keypad. Keys 13-29 are colored with a particular color, e.g., orange, and may carry a physical attribute such as a raised surface to distinguish these nine keys when they are touched by the user. Thus, the user can easily find one of the nine keys by moving the finger to the appropriate location of the key.

In addition, there are three rectangular shaped keys 31, 33, and 35 located respectively at the bottom and right side of keypad 11 as shown. Keys 31-35 are colored with a particular color, e.g., green in order to provide a visual distinction between keys 31-35 and keys 13-29. Keys 31-35 may also include a physical attribute to provide a touch distinction if desired.

Behind keypad 11 and beneath each one of the twelve keys 13-35, capacitance resistance electronics (not shown) is used to detect depression touches of these keys and sliding motions on the area adjacent to the keys. As understood, such capacitive resistance electronics have electrical properties which change in accordance with the touch on the key to which the electronics are associated. Optionally, traditional contact switches, which open and close to indicate pressure at a certain point on a key, may be located behind each of the twelve keys to support traditional tactile selection.

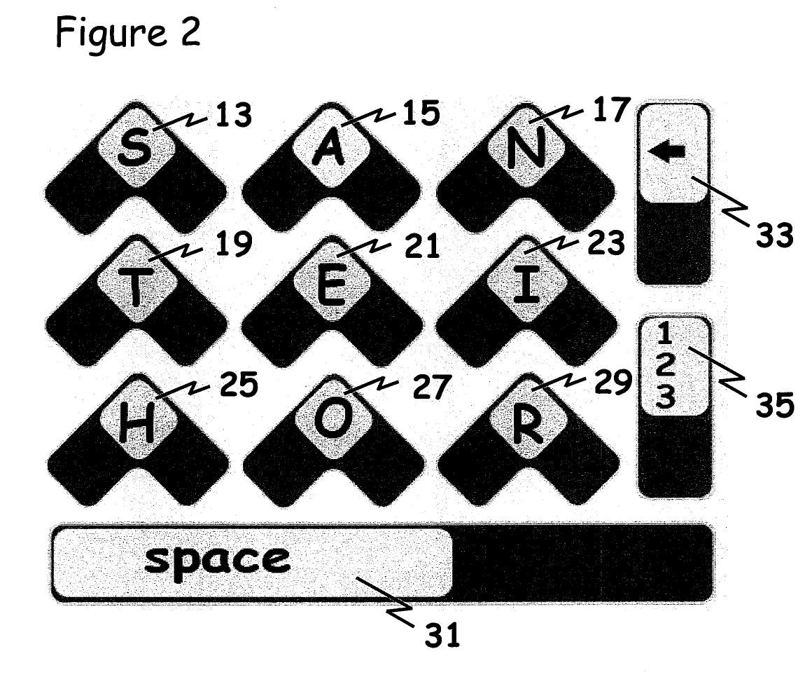

Referring to FIG. 2, the nine letters S, A, N, T, E, I, H, O, R, are assigned to keys 13-29, respectively, and each key carries its own respective letter for visual recognition. In addition, keys 31, 33, and 35 are respectively assigned “space,” “backspace” (indicated by a left pointing arrow), and the “number shift” (indicated by “123”). Keys 31-35 carry visual indicia for recognition accordingly.

To enter these characters, the user will depress or touch one of keys 13-29 which will actuate the capacitance electronics (or contact switch) beneath the selected key. Depression or touch of the “space” key enters a space. The “number shift” key is depressed to change the assigned characters on keys 13-29 from letters to numbers which will be actuated, as described below.

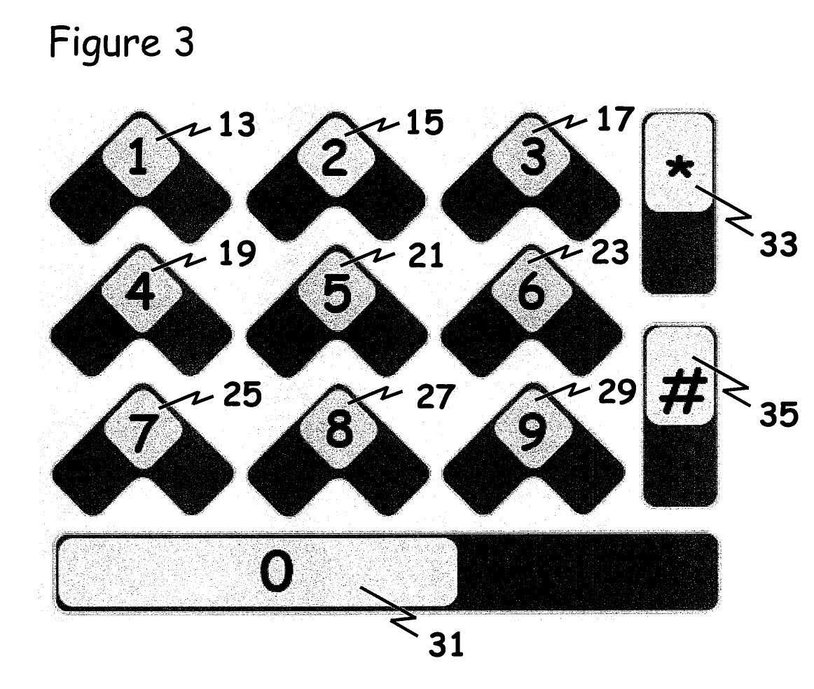

Referring to FIG. 3, the numerals 1, 2, 3, 4, 5, 6, 7, 8, 9, are assigned to keys 13-29; the numeral 0 is assigned to key 31; the symbol * is assigned to key 33; and the symbol # is assigned to key 35. To enter these numerals/symbols, the user will depress or touch the assigned key which will actuate the capacitance electronics (or contact switch) beneath the selected key.

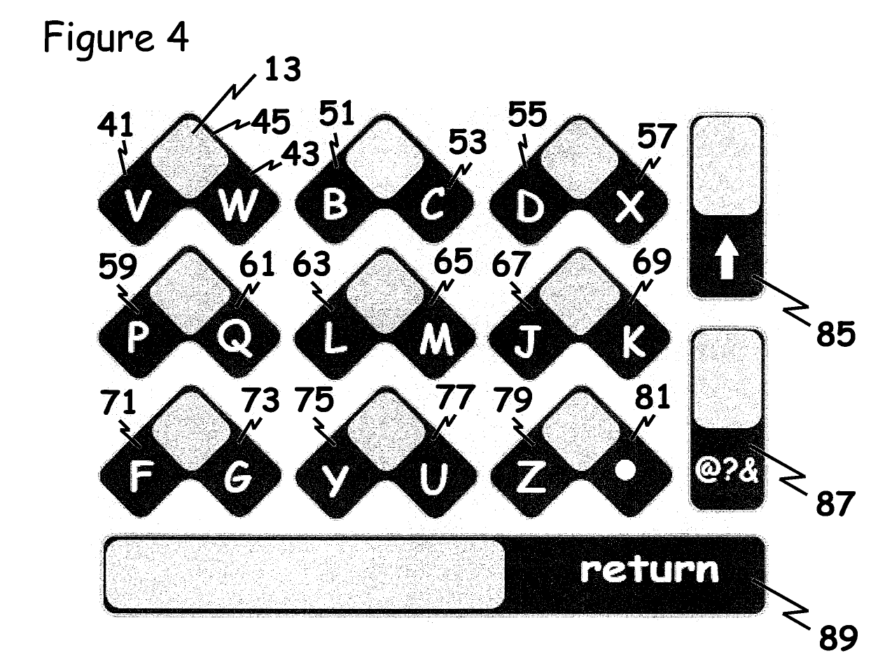

Referring to FIG. 4, two designated areas 41, 43 are located adjacent key 13. Area 41 includes the visual indicia “V” and area 43 includes the visual indicia “W”. Areas 41, 43 are colored with a particular color, e.g., grey or brown, which is different and distinct visually from the color of key 13. Both of the letters “V” and “W” are considered to be letters less frequently used.

In addition, areas 41, 43 may include a physical attribute to distinguish areas 41, 43 from key 13. For example, areas 41, 43 may be an indentation or depression in the surface of keypad 11 and wherein the top diamond surface 45 of key 13 is raised above areas 41, 43. Areas 41, 43 may be shaped to gradually lower or move away from the flat surface 45. Thus, the user feels the finger action of moving from key surface 45 into key surface 41 or 43. That is, the user begins with his/her finger on surface 45 and then moves the finger into areas 41 or 43.

Electronics or switches beneath key 13 monitor this finger movement from surface 45 into area 41 or 43. For example, capacitance resistance electronics may be located under the areas 41-45. Optionally, area 45 can have a contact switch in addition to or instead of the capacitance resistance electronics.

As also shown in FIG. 4, the letters (which may also be considered less frequently used) B, C, D, X, P, Q, L, M, J, K, F, G, Y, U, Z, “caps lock,” “symbol shift,” and “return” are entered by sliding of the finger into respective designated areas 51, 53, 55, 57, 59, 61, 63, 65, 67, 69, 71, 73, 75, 77, 79, 81, 85, 87, and 89 located adjacent to the twelve primary keys. Each designated area 41, 43, 51-91 are all colored the same (e.g., grey or brown) and may all have a unique physical attributes (e.g., indented groove). As will suggest itself, other finger actions may be detected, such as the angle of finger movement, the distance of movement, and the speed of movement.

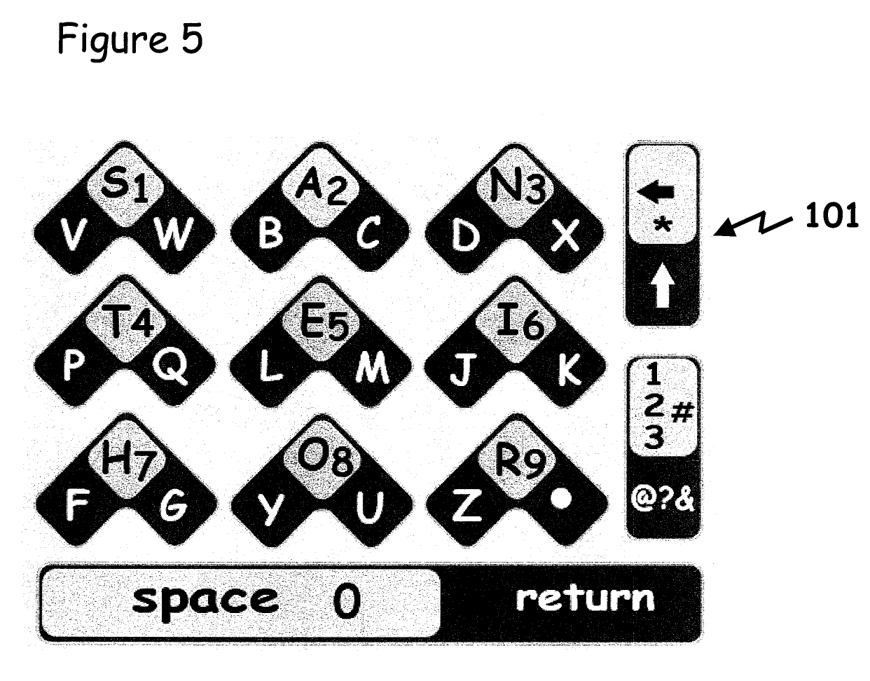

Referring to FIG. 5, the complete layout of a keypad 101 with all numbers, letters, punctuation, and control is shown. Both letter indicia and numeral indicia may be placed on keys 13-29, and letter indicia may be of one color and numeral indicia of another color.

Electrical signals that are generated by contact switches and capacitance resistance beneath the keys are sent to a microprocessor or other processing circuitry. Such a microprocessor includes software which responds to the electrical signals from the contact switches to identify alphanumeric characters or commands. Once identified, the software appropriately handles the data, as for example, dialing of an eleven digit telephone number or creation of a specific word or sentence.

Separate from the keypad, a display may be connected to the system and controlled by the microprocessor to visually present the characters that are typed into the system by the user. This facilitates learning of finger movements to achieve data entry. Also, audio feedback can be provided to validate that a character has been entered or to identify the character.

While a particular embodiment of the invention has been shown and described, it will be understood, of course, that the invention is not limited thereto since modifications can be made by persons skilled in the art.

Referring to FIG. 5, Table 1, and Table 2, letters are specifically assigned to increase the ease and speed of entering text. Referring to Table 1, the nine most frequently used letters are assigned to the nine primary alphanumeric keys. Note that these nine letters make up approximately 70% of the letters that are used in commonly written text. Referring to Table 2, many common words can be entered by touching or depressing or sliding adjacent keys or areas. For example notice that “an,” “or,” and “you” can all be selected by depressing directly adjacent keys or key areas.

TABLE 1
LETTER FREQUENCY (% OF USE
AND MOST COMMON LETTERS)

| | | | | | |
|---|---|---|---|---|---|
| E | 13% | L | 4% | Y | 2% |
| T | 9% | D | 4% | B | 2% |
| A | 8% | C | 3% | V | 1% |
| O | 8% | U | 3% | K | 1% |
| I | 7% | M | 3% | X | 0% |
| N | 7% | F | 2% | J | 0% |
| S | 7% | P | 2% | Q | 0% |
| R | 6% | G | 2% | Z | 1% |
| H | 5% | W | 2% | | |

The most common first letter in a word in order of frequency

T, O, A, W, B, C, D, S, F, M, R, H, I, Y, E, G, L, N, O, U, J, K

The most common second letter in a word in order of frequency

H, O, E, I, A, U, N, R, T

The most common third letter in a word in order of frequency

E, S, A, R, N, I

The most common last letter in a word in order of frequency

E, S, T, D, N, R, Y, F, L, O, G, H, A, K, M, P, U, W

More than half of all words end with

E, T, D, S

Letters most likely to follow E in order of frequency

R,S,N,D

TABLE 2
FULL AND PARTIAL WORD FREQUENCY

| | |
|---|---|
| 1 | the |
| 2 | of |
| 3 | and |
| 4 | a |
| 5 | to |
| 6 | in |
| 7 | is |
| 8 | you |
| 9 | that |
| 10 | it |
| 11 | he |
| 12 | was |
| 13 | for |
| 14 | on |
| 15 | are |
| 16 | as |
| 17 | with |
| 18 | his |
| 19 | they |
| 20 | I |
| 21 | at |
| 22 | be |
| 23 | this |
| 24 | have |
| 25 | from |
| 26 | or |
| 27 | one |
| 28 | had |
| 29 | by |
| 30 | word |
| 31 | but |
| 32 | not |
| 33 | what |
| 34 | all |
| 35 | were |
| 36 | we |
| 37 | when |
| 38 | your |
| 39 | can |
| 40 | said |
| 41 | there |
| 42 | use |
| 43 | an |
| 44 | each |
| 45 | which |
| 46 | she |
| 47 | do |
| 48 | how |
| 49 | their |
| 50 | if |
| 51 | will |
| 52 | up |
| 53 | other |
| 54 | about |
| 55 | out |
| 56 | many |
| 57 | then |
| 58 | them |
| 59 | these |
| 60 | so |
| 61 | some |
| 62 | her |
| 63 | would |
| 64 | make |
| 65 | like |
| 66 | him |
| 67 | into |
| 68 | time |
| 69 | has |
| 70 | look |
| 71 | two |
| 72 | more |
| 73 | write |
| 74 | go |
| 75 | see |
| 76 | number |
| 77 | no |
| 78 | way |
| 79 | could |
| 80 | people |
| 81 | my |
| 82 | than |
| 83 | first |
| 84 | water |
| 85 | been |
| 86 | call |
| 87 | who |
| 88 | oil |
| 89 | its |
| 90 | now |
| 91 | find |
| 92 | long |
| 93 | down |
| 94 | day |
| 95 | did |
| 96 | get |
| 97 | come |
| 98 | made |
| 99 | may |
| 100 | part |

### Digraph Frequency

th he an in er on re ed nd ha at en es of nt ea ti to io le is ou ar as de rt ve

### Trigraph Frequency

the and tha ent ion tio for nde has nce tis oft men

### Double Letter Frequency

ss ee tt ff ll mm oo

### Top Twenty Most Used Words in Written English

the of to in and a for was is that on at he with by be it an as his

### Top Twenty Most Used Words in Spoken English

the and I to of a you that in it is yes was this but on well he have for

### Two Letter Word Frequency

of to in it is be as at so we he by or on do if me my up an go no us am

### Three Letter Word Frequency

the and for are but not you all any can had her was one our out day get has him his how man new now old see two way who boy did its let put say she too use

### Four Letter Word Frequency

that with have this will your from they know want been good much some time very when come here just like long make many more only over such take than them well were

What is claimed is:

1. A method of data entry of a plurality of symbols including individual alphanumeric characters, using a keypad having a plurality of keys and circuitry to detect movement relative to a key, comprising:
(i) touching or pressing a first key of a keypad to identify a first alphanumeric character;
ii) touching said first key and sliding from said first key to a location adjacent to said first key to identify a second alphanumeric character different from said first alphanumeric character.

2. The method of claim 1 wherein said touching steps are performed by the user's finger or thumb.

3. The method of claim 1 wherein said touching steps are performed by a touch device such as a stylus.

4. The method of claim 1 and including a plurality of locations adjacent to said first key.

5. The method of claim 1 wherein said first alphanumeric is more common than said second alphanumeric character associated with keys.

6. The method of claim 1 wherein said first key that is pressed or touched is physically unique using techniques such as plastic extrusions, embossments, or raised keys.

7. The method of claim 1 wherein the space bar, number lock key and backspace key are physically unique by using techniques such as plastic extrusions, embossments, or raised keys.

8. The method of claim 1 wherein different fill and font colors are used for keys that are pressed or touched versus keys that are selected by a sliding motion.

9. The method of claim 1 wherein the keypad is an electronic display screen.

10. The method of claim 9 wherein the sliding motion is indicated by movement of the fill color from the first said key location to said adjacent key location.

11. The method of claim 1 wherein the adjacent sliding locations are physically formed to guide the sliding motion.

12. The method of claim 1 wherein the letters are arranged adjacent to each other according to the frequency of adjacency in words in the spoken or written English language.

13. The method of claim 1 wherein the letters characters are arranged according to frequency of letter and word usage for languages other than English.

14. The method of claim 13 wherein unique characters are used for languages that do not use the Arabic alphanumeric character set.
